(19) United States
(12) Patent Application Publication
(10) Pub. No.: US 2009/0050202 A1
(43) Pub. Date: Feb. 26, 2009

(54) SOLAR CELL AND METHOD FOR FORMING THE SAME

(75) Inventors: Chen-Hsun Du, Taipei City (TW); Yun-Sheng Chung, Hsinchu City (TW); Shyuan-Fang Chen, Taipei City (TW); Chien-Rong Huang, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 11/969,225

(22) Filed: Jan. 4, 2008

Related U.S. Application Data
(60) Provisional application No. 60/957,713, filed on Aug. 24, 2007.

(51) Int. Cl. H01L 31/0224; H01L 31/04

(52) U.S. Cl. 136/261; 438/72; 257/E31.124

(57) ABSTRACT

The invention is directed to a solar cell. The solar cell comprises a silicon layer, a front side electrode and a back side electrode. The silicon layer has a first surface and a second surface. The front side electrode is located on the first surface of the silicon layer. The back side electrode is located on the second surface of the silicon layer. Further, the back side electrode comprises a passivation layer, a first conductive layer and a second conductive layer. The passivation layer is located on the second surface of the silicon layer and has a plurality of holes penetrating through the passivation layer. The first conductive layer is located on the passivation layer and is electrically connected to the silicon layer through the holes. The second conductive layer is located on the first conductive layer.

### CROSS-REFERENCE TO RELATED APPLICATION

This application claims the priority benefit of U.S. provisional application Ser. No. 60/957,713, filed on Aug. 24, 2007. The entirety of the above-mentioned patent application is hereby incorporated by reference herein and made a part of this specification.

### BACKGROUND OF THE INVENTION

1. Field of Invention

The present invention relates to a solar cell and method for forming the same.

2. Description of Related Art

Typically, the solar cell comprises a semiconductor material with a PN junction, a front side surface as the major light receiving surface and a back side surface. When light emit onto the front side surface, electrons and the corresponding holes are produced. As for the P-type semiconductor substrate, since there is an electric field generated by the PN junction within the semiconductor material, the vector of the electric field is toward to the back side surface of the solar cell. Thus, the electrons move forward to the front side surface and the holes move forward to the back side surface so that the so-called photocurrent is generated.

Conventionally, in order to provide a relatively better electric connection, a screen printed aluminum layer is formed on the back side of the solar cell. However, with the demand for decreasing the thickness of the device, the stress between the semiconductor material and the layer of metal aluminum becomes more serious to deform the solar cell after firing process of the printed metal paste.

Furthermore, in some high efficiency solar cells, an insulating layer could be formed between the semiconductor substrate and the back electrode to prevent the carrier recombination on the back side surface. But in this case, the insulating layer cannot provide a good electric connection for the solar cell. In order to penetrate through the insulating layer with the passivation ability for obtaining the metal contacts, it is necessary to perform more complex holes opening process, such as photolithography and wet etching. However, this conventional holes opening process is not cost effective. Frounhofer ISE had developed a laser fired contact process that is more adaptable to mass production than photography process. But it also expense time and cost to prepare the thick aluminum layer by PVD process. Therefore, it is necessary to develop a method for forming a solar cell with cost effective back side electrode for better passivation ability.

### SUMMARY OF THE INVENTION

The invention provides a solar cell. The solar cell comprises a silicon layer, a front side electrode and a back side electrode. The silicon layer has a first surface and a second surface. The front side electrode is located on the first surface of the silicon layer. The back side electrode is located on the second surface of the silicon layer. Further, the back side electrode comprises a passivation layer, a first conductive layer and a second conductive layer. The passivation layer is located on the second surface of the silicon layer and the passivation layer has a plurality of holes penetrating through the passivation layer and exposing a portion of the silicon layer. The first conductive layer is located on the passivation layer and conformally covers the top surfaces of the holes in the passivation layer. Moreover, the first conductive layer is electrically connected to the silicon layer through the holes. The second conductive layer is located on the first conductive layer.

The present invention also provides a method for forming a back side electrode of a solar cell and the solar cell has a silicon layer having a first surface and a second surface. The method comprises steps of forming a passivation layer on the second surface of the silicon layer. A first conductive layer is formed on the passivation layer. A laser firing process is performed for forming a plurality of holes in the passivation layer and melting a portion of the first conductive layer over the holes so that the melted portion of the first conductive layer covers the surfaces of the holes. The first conductive layer is electrically connected to the silicon layer through the holes. A second conductive layer is formed over the first conductive layer.

In the present invention, the first conductive layer is relatively thinner and is rapidly formed over the back surface of the silicon layer by using sputtering or evaporating. Therefore, the time for manufacturing a single solar cell is decreased so that the throughput for forming the solar cell is increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1E are cross-sectional views showing a method for forming a solar cell according to one embodiment of the invention.

FIG. 2 is a plot diagram showing the fill factor change of the solar cell before and after the second conductive layer is formed.

### DETAILED DESCRIPTION OF THE INVENTION

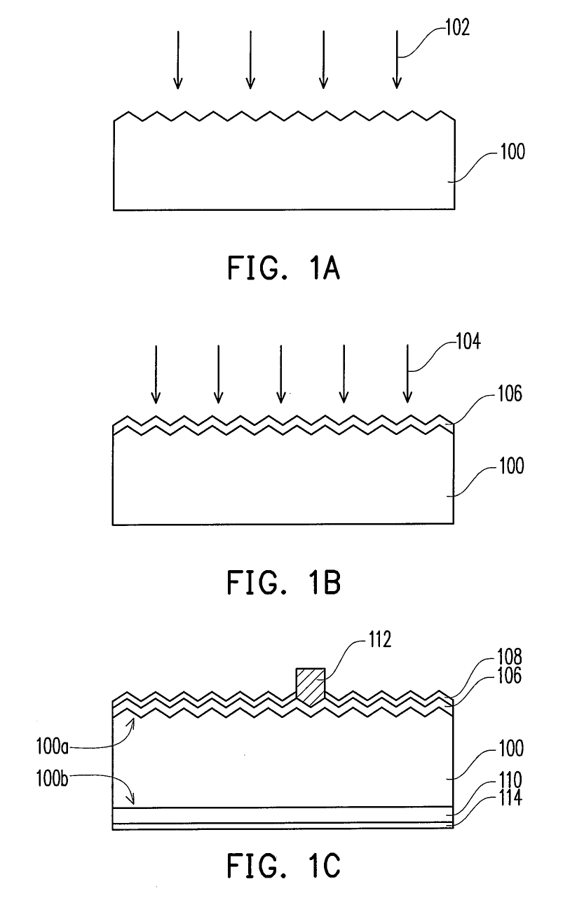

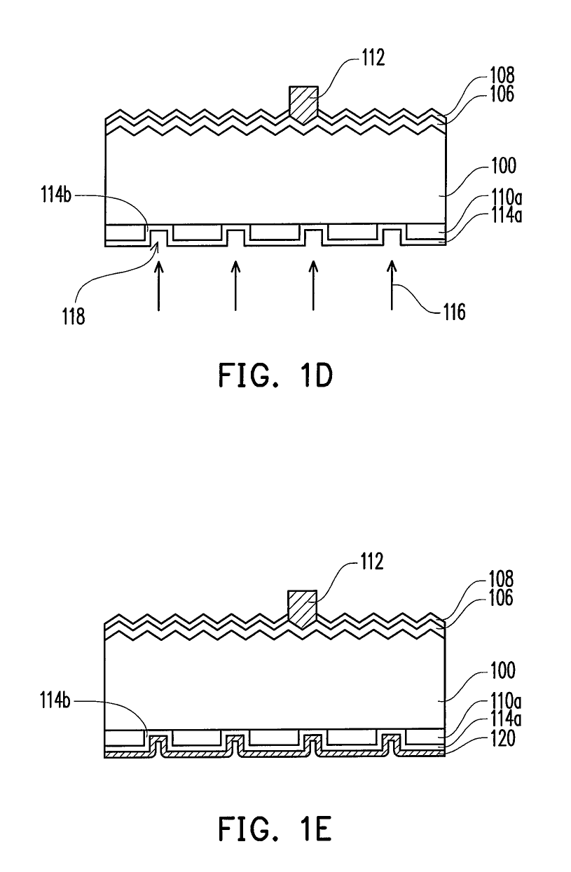

FIGS. 1A through 1E are cross-sectional views showing a method for forming a solar cell according to one embodiment of the invention. As shown in FIG. 1A, a silicon layer 100 is provided. The silicon layer 100 can be made of crystalline silicon. Further, the conductive type of the silicon layer 100 can be, for example, P-type. Then, a surface treatment 102 is performed to structure the surface of the silicon layer 100. The surface treatment 102 can be implemented by using a wet etching process.

As shown in FIG. 1B, an implantation process 104 is performed to form an emitter region 106 in the silicon layer 100 near the top surface of the silicon layer 100. The conductive type of the emitter region 106 is different from that of the silicon layer 100. Thus, the conductive type of the emitter region 106 can be N-type. In the implantation process 104, can be carried out by using POCl₃ as a doping source. Furthermore, the formation of the emitter region 106 is held at a temperature of about 840° C. and flow rate of POCl₃ of about 600 sccm. After the diffusion process, the surrounding edge of the wafer is etched using plasma etching process.

As shown in FIG. 1C, a deposition process is performed for forming an anti-reflective layer 108 and a passivation layer 110 on the front surface 100a of the silicon layer 100 and the back surface 100b of the silicon layer 100 respectively. The method for forming the anti-reflective layer 108 and the passivation layer 110 can be, for example but not limited to, low pressure chemical vapor deposition (LPCVD) or plasma enhanced chemical vapor deposition (PECVD). In the present embodiment, the anti-reflective layer 108 and the passivation layer 110 are formed in the same step. However, the invention is not limited to by the description made above. That is, the anti-reflective layer 108 and the passivation layer 110 can be formed in individual steps respectively. Moreover, the material of the anti-reflective layer 108 can be, for example but not limited to, silicon nitride or silicon oxide. Also, the material of the passivation layer 110 can be, for example but not limited to, silicon nitride or silicon oxide. Further, the material of the passivation layer 110 can be, for example but not limited to, a composite layer of a silicon nitride layer and a silicon oxide layer.

Still referring to FIG. 1C, a front side electrode 112 is formed over the front surface 100a of the silicon layer 100 and to be electrically in contact with the silicon layer 100. The material of the front side electrode 112 can be, for example, silver, copper or nickel. The method for forming the front side electrode 112 includes printing such as screen printing. Furthermore, the method for electrically connecting the front side electrode 112 with the silicon layer 100 includes a thermal process for sintering the conductive material of the front side electrode 112 to be penetrating through the anti-reflective layer to be in contact with the silicon layer 100. Also, the temperature of the thermal process is about 800˜1000° C. Then, a first conductive layer 114 is formed on the passivation layer 110. The thickness of the first conductive layer 114 is about 0.01˜0.5 μm. The material of the first conductive layer 114 can be, for example, aluminum, silver or aluminum-silver alloy. The method for forming the first conductive layer 114 sputtering and evaporation.

As shown in FIG. 1D, a laser firing process 116 is performed to form several holes 118 in the passivation layer 110a and melting a portion of the first conductive layer 114a over the holes 118 so that the melted portion 114b of the first conductive layer 114 covers the surface of the holes 118. Thus, the first conductive layer 114 is electrically connected to the silicon layer 100 through the holes 118. That is, the melted portion 114b of the first conductive layer 114a conformally covers the top surface of the holes and the first conductive layer 114 is electrically connected to the silicon layer 100 through the point contact in the holes 118. The laser used in the laser firing process can be, for example, an Nd:YAG laser.

As shown in FIG. 1E, a second conductive layer 120 is formed over the first conductive layer 114a. Thus, the passivation layer 110a, the first conductive layer 114a and the second conductive layer 120 together form a back side electrode of the solar cell. The method for forming the second conductive layer 120 can be, for example, sputtering, evaporation or electroplating. The material of the second conductive layer 120 can be, for example, nickel, copper, aluminum or silver. The thickness of the second conductive layer is about 0.5˜10 μm. Then, a sintering process is performed. The sintering process is carried out at a temperature of about 350˜450° C. and in N₂/H₂ ambiance.

In the present embodiment the front side electrode and the second conductive layer are formed in different process steps. However, the present invention is not limited to the description herein. In one embodiment, the front side electrode can be formed in the same step as the second conductive layer is formed after the step of forming electrically connecting points of the first conductive layer is carried out.

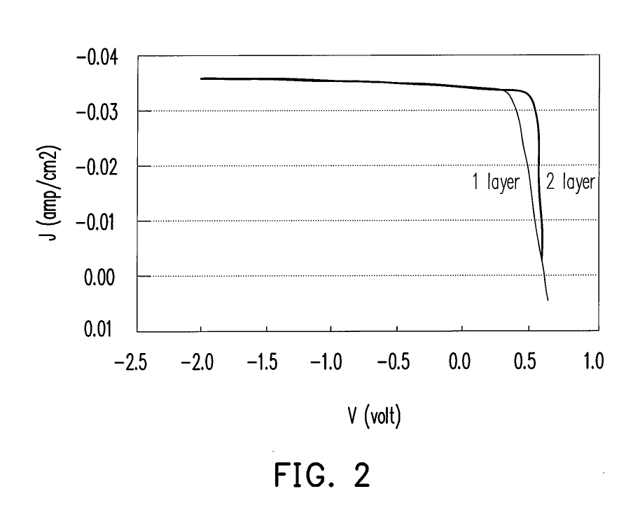

In the present invention, the first conductive layer 114 is relatively thinner and is rapidly formed over the back surface of the silicon layer 100 by using sputtering or evaporating. Therefore, the time for manufacturing a single solar cell is decreased so that the throughput for forming the solar cell is increased. Furthermore, as shown in FIG. 2, it is clear that the fill factor of the solar cell is improved as the second conductive layer is formed. That is, by forming a multi-layered structure conductive layer as the back side electrode of the solar cell, the electrical performance of the solar cell is improved.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A solar cell, comprising:
a silicon layer having a first surface and a second surface;
a front side electrode located on the first surface of the silicon layer;
a back side electrode located on the second surface of the silicon layer, wherein the back side electrode comprises:
a passivation layer located on the second surface of the silicon layer, wherein the passivation layer has a plurality of holes penetrating through the passivation layer and exposing a portion of the silicon layer;
a first conductive layer located on the passivation layer and conformally covering the top surfaces of the holes in the passivation layer, wherein the first conductive layer is electrically connected to the silicon layer through the holes; and
a second conductive layer located on the first conductive layer.

2. The solar cell of claim 1, wherein the thickness of the first conductive layer is about 0.01˜0.5 μm.

3. The solar cell of claim 1, wherein the thickness of the second conductive layer is about 0.5˜10 μm.

4. The solar cell of claim 1, wherein the material of the first conductive layer includes aluminum, silver and aluminum-silver alloy.

5. The solar cell of claim 1, wherein the material of the second conductive layer includes aluminum, nickel, copper and silver.

6. The solar cell of claim 1, wherein the material of the passivation layer includes silicon nitride and silicon oxide.

7. The solar cell of claim 1, wherein the passivation layer is a composite layer of a silicon nitride layer and a silicon oxide layer.

8. A method for forming a back side electrode of a solar cell, wherein the solar cell has a silicon layer having a first surface and a second surface, comprising:
forming a passivation layer on the second surface of the silicon layer;
forming a first conductive layer on the passivation layer;
performing a laser firing process for forming a plurality of holes in the passivation layer and melting a portion of the first conductive layer over the holes so that the melted portion of the first conductive layer covers the surfaces of the holes, wherein the first conductive layer is electrically connected to the silicon layer through the holes;
forming a second conductive layer over the first conductive layer.

9. The method of claim 8, wherein the method for forming the second conductive layer includes sputtering, evaporation and electroplating.

10. The method of claim 8, wherein the method for forming the first conductive layer includes sputtering and evaporation.

11. The method of claim 8, wherein a laser used in the laser firing process includes an Nd:YAG laser.

12. The method of claim 8, wherein the material of the passivation layer includes silicon nitride and silicon oxide.

13. The method of claim 8, wherein the passivation layer is a composite layer of a silicon nitride layer and a silicon oxide layer.

14. The method of claim 8, wherein the thickness of the first conductive layer is about 0.01˜0.5 μm.

15. The method of claim 8, wherein the thickness of the second conductive layer is about 0.5˜10 μm.

16. The method of claim 8, wherein the material of the first conductive layer includes aluminum, silver and aluminum-silver alloy.

17. The method of claim 8, wherein the material of the second conductive layer includes aluminum, nickel, copper and silver.

18. The method of claim 8, wherein, in the step of forming the passivation layer, an anti-reflective layer is formed on the first surface of the silicon layer as the passivation layer is formed on the second surface of the silicon layer.

19. The method of claim 8, wherein, in the step of forming the second conductive layer, a front side electrode is formed over the first surface of the silicon layer as the second conductive layer is formed.
